(19) United States
(12) Patent Application Publication
(10) Pub. No.: US 2024/0267016 A1
(43) Pub. Date: Aug. 8, 2024

(54) METHOD FOR MANUFACTURING ACOUSTIC WAVE ELEMENT AND ACOUSTIC WAVE ELEMENT

(71) Applicant: Murata Manufacturing Co., Ltd., Nagaokakyo-shi (JP)

(72) Inventors: Takashi YAMANE, Nagaokakyo-shi (JP); Kazunori INOUE, Nagaokakyo-shi (JP); Shinya JONOSONO, Nagaokakyo-shi (JP); Naohiro NODAKE, Nagaokakyo-shi (JP); Shintaro KUBO, Nagaokakyo-shi (JP)

(21) Appl. No.: 18/625,248

(22) Filed: Apr. 3, 2024

Related U.S. Application Data
(63) Continuation of application No. PCT/JP2022/037437, filed on Oct. 6, 2022.
(60) Provisional application No. 63/253,236, filed on Oct. 7, 2021.

(51) Int. Cl. H03H 3/02; B23K 26/38; B23K 101/36; H03H 9/02

(52) U.S. Cl. CPC H03H 3/02; B23K 26/38; H03H 9/02015; H03H 9/02228; B23K 2101/36

(57) ABSTRACT

A method for manufacturing an acoustic wave element including a support substrate, a piezoelectric material layer on the support substrate, and a functional electrode on the piezoelectric material layer, includes preparing a wafer in which the support substrate and the piezoelectric material layer are laminated, thinning the support substrate of the wafer, and after the thinning the support substrate, cutting the wafer with a dicing machine to singulate the acoustic wave element.

### CROSS REFERENCE TO RELATED APPLICATIONS

This application claims the benefit of priority to Provisional Application No. 63/253,236 filed on Oct. 7, 2021 and is a Continuation Application of PCT Application No. PCT/JP2022/037437 filed on Oct. 6, 2022. The entire contents of each application are hereby incorporated herein by reference.

### BACKGROUND OF THE INVENTION

### 1. Field of the Invention

The present disclosure relates to methods for manufacturing acoustic wave elements, and acoustic wave elements.

### 2. Description of the Related Art

For example, Japanese Unexamined Patent Application Publication No. 2012-257019 discloses an acoustic wave device utilizing a plate wave. The acoustic wave device described in Japanese Unexamined Patent Application Publication No. 2012-257019 includes a support, a piezoelectric substrate, and an interdigital transducer (IDT) electrode. The support is provided with a hollow portion. The piezoelectric substrate is provided on the support to overlap the hollow portion. The IDT electrode is provided on the piezoelectric substrate to overlap the hollow portion. In the acoustic wave device, a plate wave is excited by the IDT electrode.

### SUMMARY OF THE INVENTION

Example embodiments of the present invention provide methods for manufacturing acoustic wave elements, and acoustic wave elements each capable of reducing the size of the acoustic wave element.

A method for manufacturing an acoustic wave element according to an aspect of an example embodiment of the present disclosure is a method for manufacturing an acoustic wave element including a support substrate, a piezoelectric material layer on the support substrate, and a functional electrode on the piezoelectric material layer, the method including preparing a wafer in which the support substrate and the piezoelectric material layer are laminated, thinning the support substrate of the wafer, and after the thinning the support substrate, cutting the wafer with a dicing machine to singulate the acoustic wave element.

An acoustic wave element according to another aspect of an example embodiment of the present disclosure includes a support substrate including a first surface and a second surface opposing each other, a piezoelectric material layer on the first surface, and a functional electrode on the piezoelectric material layer, wherein a surface roughness of the second surface is rougher than a surface roughness of the piezoelectric material layer, and the support substrate has a thickness of about 250 μm or less.

According to example embodiments of the present disclosure, methods for manufacturing acoustic wave elements, and acoustic wave elements are provided, and are capable of reducing the size of the acoustic wave element.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an external appearance of an acoustic wave device of first and second aspects of example embodiments of the present invention.

FIG. 1B is a plan view illustrating an electrode structure on a piezoelectric layer.

FIG. 2 is a cross-sectional view of a portion taken along a line A-A in FIG. 1A.

FIG. 3A is a schematic elevational cross-sectional view for explaining a Lamb wave propagating through a piezoelectric film of a known acoustic wave device.

FIG. 3B is a schematic elevational cross-sectional view for explaining a wave of an acoustic wave device of an example embodiment of the present invention.

FIG. 4 is a schematic diagram illustrating a bulk wave when a voltage is applied between a first electrode and a second electrode in such a manner that a potential of the second electrode is higher than a potential of the first electrode.

FIG. 5 is a diagram depicting resonance characteristics of an acoustic wave device according to a first example embodiment of the present invention.

FIG. 6 is a diagram depicting a relationship between d/2p and a fractional bandwidth as a resonator of an acoustic wave device.

FIG. 7 is a plan view of another acoustic wave device according to the first example embodiment of the present invention.

FIG. 8 is a reference diagram depicting an example of resonance characteristics of an acoustic wave device.

FIG. 9 is a diagram depicting a relationship between a fractional bandwidth and a phase rotation quantity of spurious impedance normalized by 180 degrees as magnitude of a spurious emission in a case where a large number of acoustic wave resonators are provided.

FIG. 10 is a diagram depicting a relationship between d/2p, a metalization ratio MR, and a fractional bandwidth.

FIG. 11 is a diagram depicting a map of a fractional bandwidth with respect to Euler angles (0°, θ, ψ) of LiNbO₃ in a case where d/p is made to approach 0 as much as possible.

FIG. 12 is a partially cutaway perspective view for explaining an acoustic wave device according to the first example embodiment of the present invention.

FIG. 13 is a schematic plan view of an acoustic wave device according to a second example embodiment of the present invention.

FIG. 14 is a schematic cross-sectional view of the acoustic wave device taken along a line A-A in FIG. 13.

FIG. 15 is a flowchart for explaining a method for manufacturing the acoustic wave device in FIG. 13.

FIG. 16 is a diagram for explaining the method for manufacturing the acoustic wave device in FIG. 13.

FIG. 17 is a diagram for explaining the method for manufacturing the acoustic wave device in FIG. 13.

FIG. 18 is a diagram for explaining the method for manufacturing the acoustic wave device in FIG. 13.

FIG. 19 is a diagram for explaining the method for manufacturing the acoustic wave device in FIG. 13.

FIG. 20 is a diagram for explaining the method for manufacturing the acoustic wave device in FIG. 13.

FIG. 21 is a diagram for explaining the method for manufacturing the acoustic wave device in FIG. 13.

FIG. 22 is a diagram for explaining the method for manufacturing the acoustic wave device in FIG. 13.

FIG. 23 is a diagram for explaining the method for manufacturing the acoustic wave device in FIG. 13.

FIG. 24 is a diagram for explaining the method for manufacturing the acoustic wave device in FIG. 13.

FIG. 25 is a diagram for explaining the method for manufacturing the acoustic wave device in FIG. 13.

FIG. 26 is a diagram for explaining the method for manufacturing the acoustic wave device in FIG. 13.

FIG. 27 is a diagram for explaining the method for manufacturing the acoustic wave device in FIG. 13.

FIG. 28 is a flowchart for explaining a method for manufacturing an acoustic wave device of Modification 1 of an example embodiment of the present invention.

FIG. 29 is a flowchart for explaining a method for manufacturing an acoustic wave device of Modification 2 of an example embodiment of the present invention.

FIG. 30 is a diagram for explaining the method for manufacturing the acoustic wave device of Modification 2 of an example embodiment of the present invention.

FIG. 31 is a diagram for explaining the method for manufacturing the acoustic wave device of Modification 2 of an example embodiment of the present invention.

### DETAILED DESCRIPTION OF THE EXAMPLE EMBODIMENTS

Acoustic wave devices of first, second, and third aspects of example embodiments of the present disclosure each include a piezoelectric layer including lithium niobate or lithium tantalate, and a first electrode and a second electrode facing each other in a direction intersecting a thickness direction of the piezoelectric layer.

The acoustic wave device of the first aspect of an example embodiment of the present invention utilizes a bulk wave in a thickness-shear mode.

In the acoustic wave device of the second aspect of an example embodiment of the present invention, the first electrode and the second electrode are adjacent electrodes, and d/p is about 0.5 or less, where d is a thickness of the piezoelectric layer and p is a center-to-center distance between the first electrode and the second electrode. Thus, in the first and second aspects, a Q value can be increased even when miniaturization is advanced.

The acoustic wave device of the third aspect of an example embodiment of the present invention utilizes a Lamb wave as a plate wave. Resonance characteristics by the Lamb wave can be obtained.

An acoustic wave device of a fourth aspect of an example embodiment of the present invention of the present disclosure includes a piezoelectric layer including lithium niobate or lithium tantalate, and an upper electrode and a lower electrode opposing each other interposing the piezoelectric layer therebetween in the thickness direction of the piezoelectric layer, and utilizes a bulk wave.

Hereinafter, the present disclosure will be clarified by describing specific example embodiments of the acoustic wave devices of the first to fourth aspects of example embodiments of the present invention with reference to the drawings.

It is to be noted that the example embodiments described in the present specification are merely examples, and partial replacement or combination of the configurations can be carried out between the different example embodiments.

### First Example Embodiment

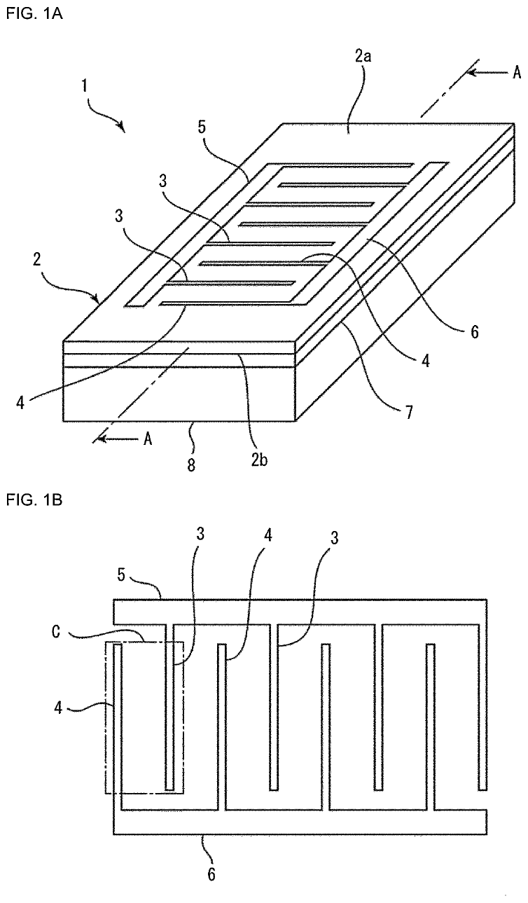

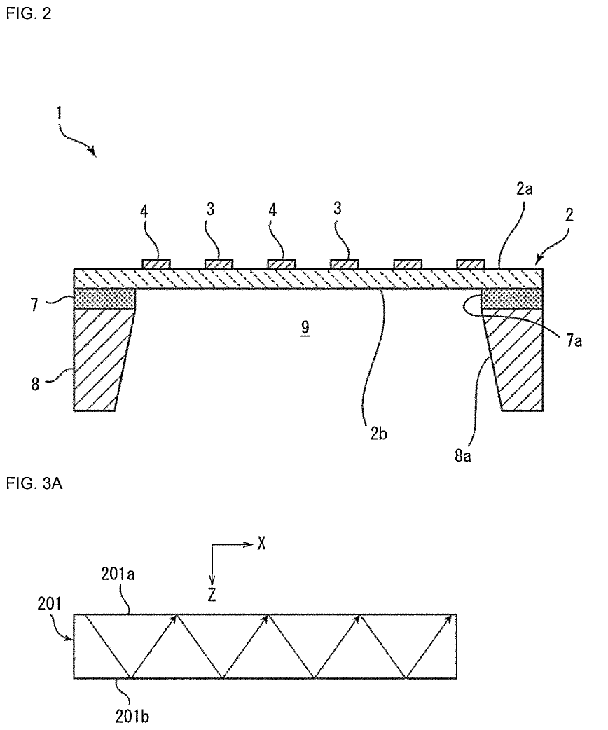

FIG. 1A is a schematic perspective view illustrating an external appearance of an acoustic wave device according to a first example embodiment regarding the first and second aspects, FIG. 1B is a plan view illustrating an electrode structure on a piezoelectric layer, and FIG. 2 is a cross-sectional view of a portion taken along a line A-A in FIG. 1A.

An acoustic wave device 1 includes a piezoelectric layer 2 including LiNbO₃. The piezoelectric layer 2 may include LiTaO₃. The cut-angle of the LiNbO₃ or the LiTaO₃ is a Z-cut in the present example embodiment, but may be a rotated Y-cut or X-cut. A propagation orientation of ±30° of the Y propagation and X propagation is preferred. The thickness of the piezoelectric layer 2 is not particularly limited, but is preferably about 50 nm or more and about 1000 nm or less, for example, in order to effectively excite the thickness-shear mode.

The piezoelectric layer 2 includes first and second principal surfaces 2a and 2b opposing each other. Electrodes 3 and 4 are provided on the first principal surface 2a. The electrode 3 is an example of the “first electrode”, and the electrode 4 is an example of the “second electrode”. In FIGS. 1A and 1B, a plurality of the electrodes 3 is a plurality of first electrode fingers connected to a first busbar 5. A plurality of the electrodes 4 is a plurality of second electrode fingers connected to a second busbar 6. The plurality of electrodes 3 and the plurality of electrodes 4 interdigitate with each other.

The electrodes 3 and 4 may have a rectangular or substantially rectangular shape and extend a longitudinal direction. The electrode 3 and the adjacent electrode 4 face each other in a direction orthogonal to the longitudinal direction. The plurality of electrodes 3, the plurality of electrodes 4, the first busbar 5, and the second busbar 6 define an interdigital transducer (IDT) electrode. The longitudinal direction of the electrodes 3 and 4 and the direction orthogonal to the longitudinal direction of the electrodes 3 and 4 are both directions intersecting the thickness direction of the piezoelectric layer 2. Therefore, it can be said that the electrode 3 and the adjacent electrode 4 face each other in a direction intersecting the thickness direction of the piezoelectric layer 2.

The longitudinal direction of the electrodes 3 and 4 may 4 may be interchanged with the direction orthogonal to the longitudinal direction of the electrodes 3 and 4 illustrated in FIGS. 1A and 1B. That is, in FIGS. 1A and 1B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 1A and 1B.

A plurality of structures each including a pair of electrodes including the electrode 3 connected to one potential and the electrode 4 connected to the other potential adjacent to each other is provided in a direction orthogonal to the longitudinal direction of the electrodes 3 and 4. In this case, “the electrode 3 and the electrode 4 are adjacent to each other” does not mean that the electrode 3 and the electrode 4 are to be in direct contact with each other, but means that the electrode 3 and the electrode 4 are positioned with a gap interposed therebetween.

When the electrode 3 and the electrode 4 are adjacent to each other, none of the electrodes including the other electrodes 3 and 4 connected to a hot electrode, a ground electrode, or the like are located between the electrode 3 and the electrode 4. The number of pairs of electrodes including the electrodes 3 and 4 is not limited to an integer, and may be 1.5, 2.5, or the like. The center-to-center distance between the electrodes 3 and 4, that is, the pitch therebetween is preferably in a range from about 1 μm to about 10 μm, for example. The center-to-center distance between the electrodes 3 and 4 is a distance between the center of a width dimension of the electrode 3 in the direction orthogonal to the longitudinal direction of the electrode 3 and the center of a width dimension of the electrode 4 in the direction orthogonal to the longitudinal direction of the electrode 4. In a case where at least one of the electrodes 3 and 4 is allowed to be provided plurally (in a case where 1.5 or more pairs of electrodes are provided while taking a pair of electrodes 3 and 4 as a pair of electrodes), the center-to-center distance between the electrodes 3 and 4 refers to an average value of the respective center-to-center distances between the adjacent electrodes 3 and 4 among the 1.5 or more pairs of electrodes 3 and 4. The widths of the electrodes 3 and 4, that is, the dimensions in the facing direction of the electrodes 3 and 4 are preferably in a range from about 150 nm to about 1000 nm, for example. The center-to-center distance between the electrodes 3 and 4 is a distance between the center of the dimension (width dimension) of the electrode 3 in the direction orthogonal to the longitudinal direction of the electrode 3 and the center of the dimension (width dimension) of the electrode 4 in the direction orthogonal to the longitudinal direction of the electrode 4.

In the present example embodiment, since the Z-cut piezoelectric layer is used, the direction orthogonal to the longitudinal direction of the electrodes 3 and 4 is a direction orthogonal to a polarization direction of the piezoelectric layer 2. This is not the case when a piezoelectric material with another cut-angle is used as the piezoelectric layer 2. Here, the term “orthogonal” is not limited only to a case of being strictly orthogonal, and is allowed to be substantially orthogonal (an angle formed between the direction orthogonal to the longitudinal direction of the electrodes 3 and 4 and the polarization direction is, for example, 90°±10°).

A support 8 is laminated on the second principal surface 2b side of the piezoelectric layer 2 with an insulating layer 7 interposed therebetween. The insulating layer 7 and the support 8 have a frame shape and include cavities 7a and 8a, as illustrated in FIG. 2. Thus, a hollow portion 9 is provided. The hollow portion 9 is provided not to hinder vibrations of an excitation region C of the piezoelectric layer 2. Accordingly, the support 8 is laminated on the second principal surface 2b with the insulating layer 7 interposed therebetween at a position not overlapping a portion where at least one pair of electrodes 3 and 4 is provided. The insulating layer 7 need not be provided. Therefore, the support 8 can be directly or indirectly laminated on the second principal surface 2b of the piezoelectric layer 2.

The insulating layer 7 includes silicon oxide. As the material of the insulating layer 7, an appropriate insulating material such as silicon oxynitride or alumina may be used other than silicon oxide. The support 8 includes Si. The plane orientation of a surface of the Si on the piezoelectric layer 2 side may be (100), (110), or (111). Preferably, high-resistance Si having a resistivity of about 4 kΩ or more, for example, is used. Note that the support 8 may include an appropriate insulating material or semiconductor material. As the material of the support 8, for example, a piezoelectric material such as aluminum oxide, lithium tantalate, lithium niobate or quartz, various ceramics such as alumina, magnesia, sapphire, silicon nitride, aluminum nitride, silicon carbide, zirconia, cordierite, mullite, steatite or forsterite, a dielectric such as diamond or glass, or a semiconductor such as gallium nitride may be used.

Suitable materials of the plurality of electrodes 3 and 4 and the first and second busbars 5 and 6 are metals or alloys such as Al or an AlCu alloy. In the present example embodiment, the electrodes 3 and 4 and the first and second busbars 5 and 6 each have a structure in which an Al film is laminated on a Ti film. Note that a close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics utilizing a bulk wave in a thickness-shear mode excited in the piezoelectric layer 2.

In the acoustic wave device 1, d/p is about 0.5 or less, where d is the thickness of the piezoelectric layer 2 and p is the center-to-center distance between any adjacent electrodes 3 and 4 among the plurality of pairs of electrodes 3 and 4. Due to this, the bulk wave in the thickness-shear mode is effectively excited, and favorable resonance characteristics can be obtained. More preferably, d/p is about 0.24 or less, and in this case, further more favorable resonance characteristics can be obtained.

As in the present example embodiment, in the case where at least one of the electrodes 3 and 4 is allowed to be provided plurally, that is, in the case where 1.5 or more pairs of electrodes 3 and 4 are provided while taking the electrodes 3 and 4 as a pair of electrodes, the center-to-center distance p between the electrodes 3 and 4 adjacent to each other refers to an average distance of the respective center-to-center distances between the adjacent electrodes 3 and 4.

The acoustic wave device 1 of the present example embodiment has the above-described configuration, whereby a drop in the Q value is unlikely to occur even when the number of pairs of electrodes 3 and 4 is decreased to achieve a reduction in size. This is because the resonator is such a resonator that does not need reflectors at both sides thereof and propagation loss is small. Since the bulk wave in the thickness-shear mode is utilized, the above-mentioned reflectors are not needed.

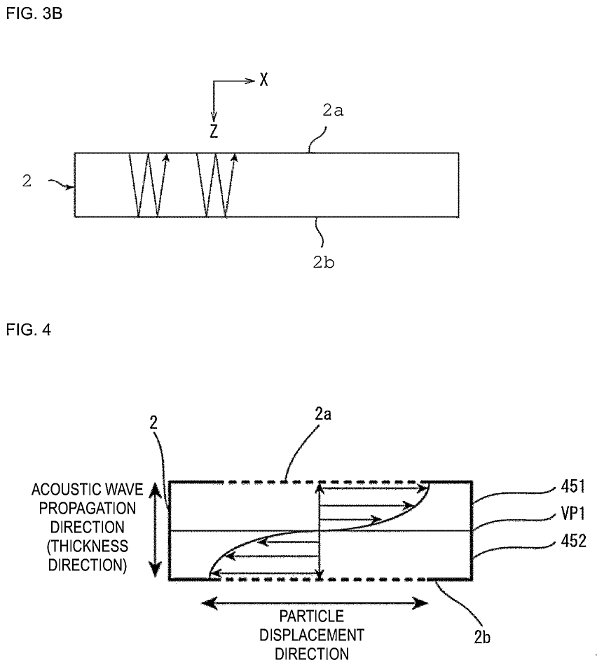

A difference between a Lamb wave utilized in a known acoustic wave device and the bulk wave in the thickness-shear mode will be described with reference to FIGS. 3A and 3B.

FIG. 3A is a schematic elevational cross-sectional view for explaining a Lamb wave propagating through a piezoelectric film of a known acoustic wave device. A known acoustic wave device is described in, for example, Japanese Unexamined Patent Application Publication No. 2012-257019. As illustrated in FIG. 3A, in the known acoustic wave device, a wave propagates in a piezoelectric film 201 as indicated by arrows. In the piezoelectric film 201, a first principal surface 201a and a second principal surface 201b oppose each other, and a thickness direction connecting the first principal surface 201a and the second principal surface 201b is a Z direction. An X direction is a direction in which the electrode fingers of the IDT electrode are aligned. As illustrated in FIG. 3A, in the case of the Lamb wave, the wave propagates in the X direction as depicted in the drawing. Although the piezoelectric film 201 vibrates as a whole because the wave is a plate wave, the wave propagates in the X direction, and thus reflectors are disposed at both sides to obtain resonance characteristics. This causes propagation loss of the wave, and when it is attempted to achieve the miniaturization, that is, when the number of pairs of electrode fingers is reduced, the Q value is lowered.

In contrast, as illustrated in FIG. 3B, in the acoustic wave device 1 of the present example embodiment, since the vibration is displaced in a thickness-shear direction, the wave propagates in a direction connecting the first principal surface 2a and the second principal surface 2b of the piezoelectric layer 2, that is, substantially propagates in the Z direction, and resonates. That is, the X-direction component of the wave is significantly smaller than the Z-direction component thereof. Since the resonance characteristics are obtained by the propagation of the wave in the Z direction, no reflector is needed. Accordingly, the propagation loss caused when the wave propagates to the reflector does not occur. Therefore, even in a case where the number of pairs of electrodes including the electrodes 3 and 4 is decreased to achieve a reduction in size, a drop in the Q value is unlikely to occur.

As illustrated in FIG. 4, an amplitude direction of a bulk wave in the thickness-shear mode is reversed between a first region 451 included in the excitation region C of the piezoelectric layer 2 and a second region 452 included in the excitation region C thereof. FIG. 4 schematically illustrates the bulk wave when a voltage is applied between the electrode 3 and the electrode 4 in such a manner that a potential of the electrode 4 is higher than a potential of the electrode 3. In the excitation region C, the first region 451 is a region between the first principal surface 2a and a virtual plane VP1 being orthogonal to the thickness direction of the piezoelectric layer 2 and dividing the piezoelectric layer 2 into two parts. In the excitation region C, the second region 452 is a region between the virtual plane VP1 and the second principal surface 2b.

As described above, in the acoustic wave device 1, at least one pair of electrodes including the electrodes 3 and 4 is provided, but the purpose is not to propagate the wave in the X direction. Therefore, it is not absolutely necessary that the number of pairs of electrodes including the electrodes 3 and 4 is plural. In other words, it is only necessary to provide at least one pair of electrodes.

For example, the electrode 3 is an electrode connected to a hot potential, and the electrode 4 is an electrode connected to a ground potential. The electrode 3 may be connected to the ground potential, and the electrode 4 may be connected to the hot potential. In the present example embodiment, as described above, at least one pair of electrodes refers to electrodes connected to the hot potential or electrodes connected to the ground potential, and no floating electrode is provided.

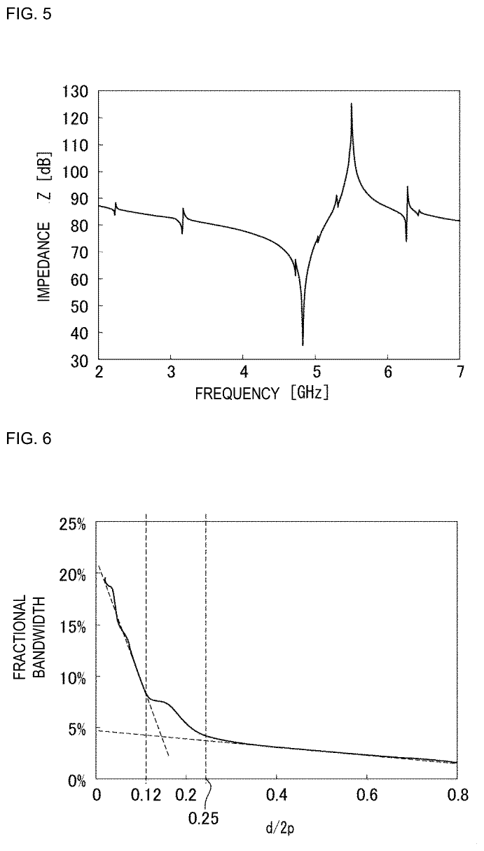

FIG. 5 is a diagram depicting resonance characteristics of the acoustic wave device according to the first example embodiment of the present disclosure. Example design parameters of the acoustic wave device 1 having the depicted resonance characteristics are as follows.

Piezoelectric layer 2: LiNbO₃ with Euler angles (0°, 0°, 90°), thickness=400 nm.

When viewed in a direction orthogonal to the longitudinal direction of the electrodes 3 and 4, the length of a region where the electrodes 3 and 4 overlap each other, i.e., the length of the excitation region C is 40 μm, the number of pairs of electrodes including the electrodes 3 and 4 is 21, the center-to-center distance between the electrodes is 3 μm, the width of the electrodes 3 and 4 is 500 nm, and d/p is 0.133.

Insulating layer 7: a silicon oxide film having a thickness of 1 μm.

### Support 8: Si.

The length of the excitation region C refers to a dimension of the excitation region C along the longitudinal direction of the electrodes 3 and 4.

In the present example embodiment, the distance between the electrodes of the pair of electrodes including the electrodes 3 and 4 was made equal across all of the plurality of pairs. That is, the electrodes 3 and the electrodes 4 were positioned at an equal pitch.

As is clear from FIG. 5, although no reflector is provided, favorable resonance characteristics with a fractional bandwidth being about 12.5% are obtained, for example.

As described above, in the present example embodiment, d/p is about 0.5 or less, and more preferably is about 0.24 or less, where d is the thickness of the piezoelectric layer 2 and p is the center-to-center distance between the electrodes 3 and 4. This will be described with reference to FIG. 6.

Similar to the acoustic wave device having obtained the resonance characteristics depicted in FIG. 5, a plurality of the acoustic wave devices was achieved through changing d/2p. FIG. 6 is a diagram depicting a relationship between the above-mentioned d/2p and a fractional bandwidth as a resonator of the acoustic wave device.

As is clear from FIG. 6, when d/2p exceeds about 0.25, i.e., when d/p is greater than about 0.5, the fractional bandwidth is less than about 5% even when d/p is adjusted, for example. In contrast, when d/2p≤ about 0.25, i.e., d/p≤ about 0.5, the fractional bandwidth can be increased to about 5% or more by changing d/p within the above range, that is, a resonator having a high coupling coefficient can be provided, for example. When d/2p is about 0.12 or less, i.e., when d/p is about 0.24 or less, the fractional bandwidth can be increased to about 7% or more, for example. In addition, when d/p is adjusted within this range, a resonator having a wider fractional bandwidth can be obtained, and a resonator having a higher coupling coefficient can be achieved. Accordingly, it is found that, by setting d/p to be equal to or smaller than about 0.5 as in the acoustic wave device of the second aspect of an example embodiment of the present disclosure, a resonator having a high coupling coefficient utilizing the bulk wave in the thickness-shear mode can be provided.

As described above, at least a pair of electrodes may be one pair, and the above-mentioned p is the center-to-center distance between the adjacent electrodes 3 and 4 in the case of one pair of electrodes. In the case of 1.5 or more pairs of electrodes, it is sufficient that the average distance of the respective center-to-center distances between the adjacent electrodes 3 and 4 is taken as p.

As for the thickness d of the piezoelectric layer, in the case where there is a variation in thickness of the piezoelectric layer 2, it is sufficient to adopt a value obtained by averaging the thicknesses thereof.

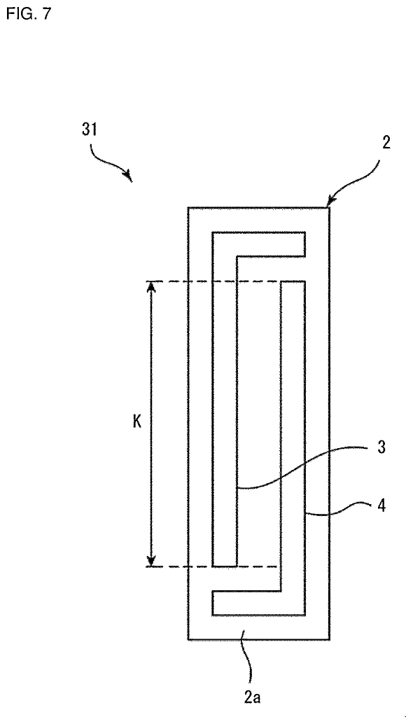

FIG. 7 is a plan view of another acoustic wave device according to the first example embodiment of the present disclosure. In an acoustic wave device 31, a pair of electrodes including electrodes 3 and 4 is provided on a first principal surface 2a of a piezoelectric layer 2. Note that K in FIG. 7 is an overlap width. As described above, in the acoustic wave device 31 of the present disclosure, the number of pairs of electrodes may be one. In this case as well, when the above-mentioned d/p is equal to or less than about 0.5, a bulk wave in the thickness-shear mode can be effectively excited.

In the acoustic wave device 1, it is desirable that, with respect to an excitation region where any adjacent electrodes 3 and 4 among the plurality of electrodes 3 and electrodes 4 overlap each other when viewed in the direction in which the above adjacent electrodes 3 and 4 face each other, a metalization ratio MR of the above adjacent electrodes 3 and 4 satisfies a relation of MR≤ about 1.75 (d/p)+0.075, for example. That is, when viewed in the direction in which the plurality of first electrode fingers and the plurality of second electrode fingers adjacent to each other face each other, a region in which the plurality of first electrode fingers and the plurality of second electrode fingers overlap each other is an excitation region (overlap region). When the metalization ratio of the plurality of first electrode fingers and the plurality of second electrode fingers with respect to the excitation region is represented by MR, it is preferable to satisfy the relation of MR≤ about 1.75 (d/p)+0.075, for example. In this case, a spurious emission may be effectively reduced.

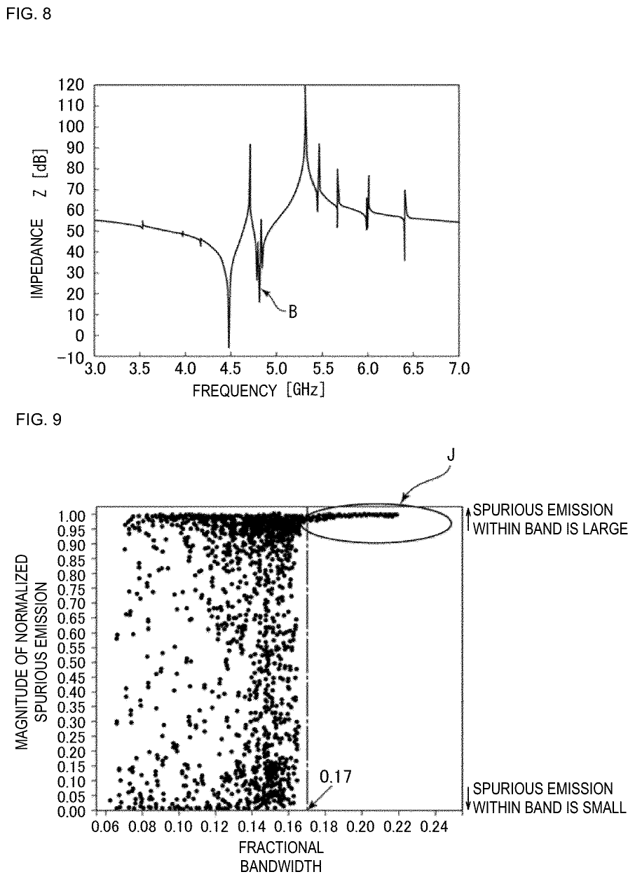

This will be described with reference to FIGS. 8 and 9. FIG. 8 is a reference diagram depicting an example of the resonance characteristics of the acoustic wave device 1. A spurious emission indicated by an arrow B appears between a resonant frequency and an anti-resonant frequency. Note that d/p was equal to about 0.08 and Euler angles of LiNbO₃ were (0°, 0°, 90°), for example. The metalization ratio MR was set to about 0.35, for example.

The metalization ratio MR will be explained with reference to FIG. 1B. In the electrode structure illustrated in FIG. 1B, when a certain pair of electrodes 3 and 4 is focused on, it is considered that only this pair of electrodes 3 and 4 is provided. In this case, a section surrounded by a chain line C is an excitation region. When the electrode 3 and the electrode 4 are viewed in a direction orthogonal to the longitudinal direction of the electrodes 3 and 4, that is, viewed in the facing direction, the excitation region refers to a region in the electrode 3 that overlaps the electrode 4, a region in the electrode 4 that overlaps the electrode 3, and a region between the electrode 3 and the electrode 4 where the electrode 3 and the electrode 4 overlap each other. The ratio of the area of the electrodes 3 and 4 in the excitation region C to the area of the excitation region is the metalization ratio MR. That is, the metalization ratio MR is the ratio of the area of a metalization portion to the area of the excitation region.

When a plurality of pairs of electrodes is provided, it is sufficient that the ratio of the metalization portion included in the entire excitation region to the total area of the excitation region is defined as MR.

In accordance with the present example embodiment, FIG. 9 is a diagram depicting a relationship between a fractional bandwidth and a phase rotation quantity of spurious impedance normalized by 180 degrees as magnitude of a spurious emission in a case where a large number of acoustic wave resonators are provided. The fractional bandwidth was adjusted by variously changing the thickness of the piezoelectric layer, the dimensions of the electrodes, and the like. FIG. 9 depicts a result obtained when a piezoelectric layer including Z-cut LiNbO₃ is used, but the same tendency is obtained when a piezoelectric layer with another cut-angle is used.

In a region surrounded by an ellipse J in FIG. 9, a spurious emission is increased to be about 1.0, for example. As is clear from FIG. 9, in a case where the fractional bandwidth exceeds about 0.17, that is, when the fractional bandwidth exceeds about 17%, a large spurious emission having a spurious level of about 1 or more appears in a pass band even when parameters defining the fractional bandwidth are changed, for example. That is, as in the resonance characteristics depicted in FIG. 8, a large spurious emission indicated by the arrow B appears within the band. Accordingly, the fractional bandwidth is preferably about 17% or less, for example. In this case, the spurious emission may be reduced by adjusting the thickness of the piezoelectric layer 2, the dimensions of the electrodes 3 and 4, or the like.

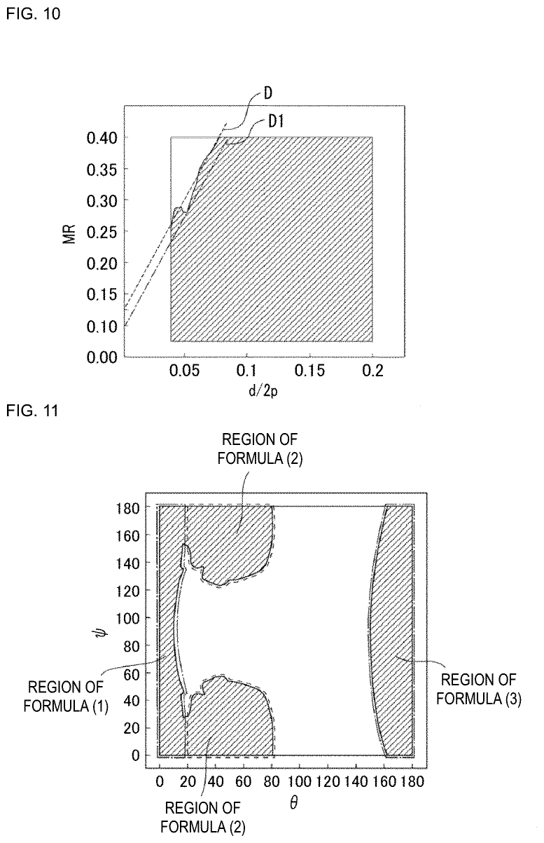

FIG. 10 is a diagram depicting a relationship between d/2p, a metalization ratio MR, and a fractional bandwidth. In the above-discussed acoustic wave device, various acoustic wave devices having different values of d/2p and MR were provided, and the fractional bandwidths were measured. A hatched portion on the right side of a broken line D in FIG. 10 is a region where the fractional bandwidth is about 17% or less, for example. A boundary between the hatched region and the unhatched region is represented by an expression of MR=about 3.5 (d/2p)+0.075, for example. That is, MR is equal to about 1.75 (d/p)+0.075, for example. Accordingly, the following relation is preferably satisfied: MR≤ about 1.75 (d/p)+0.075, for example. In this case, the fractional bandwidth is easily set to about 17% or less, for example. More preferred is a region on the right side of an expression of MR=about 3.5 (d/2p)+0.05, which is indicated by a chain line D1 in FIG. 10. That is, when a relation of MR≤ about 1.75 (d/p)+0.05 is satisfied, the fractional bandwidth can be reliably set to about 17% or less, for example.

FIG. 11 is a diagram depicting a map of a fractional bandwidth with respect to Euler angles (0°, θ, ψ) of LiNbO₃ in a case where d/p is made to approach 0 as much as possible. A hatched portion in FIG. 11 is a region where a fractional bandwidth of at least about 5% or more is obtained, for example. When the range of the region is approximated, obtained are ranges represented by

### Formula (1), Formula (2), and Formula (3).

(0°±10°,0° to 20°,optional ψ) Formula(1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Formula(2)

(0°±10°,[180°−30°(1−(ψ−90)²/8100)^{1/2}] to 180°, optional ψ) Formula(3)

Therefore, the above-described Euler angles range of Formula (1), (2), or (3) is preferred because the fractional bandwidth can be sufficiently widened.

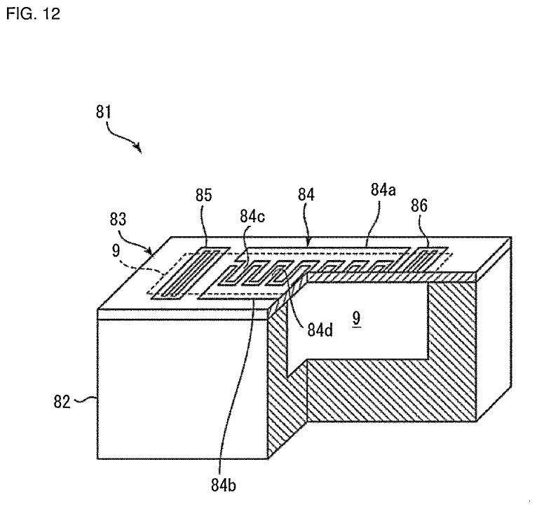

FIG. 12 is a partially cutaway perspective view for explaining an acoustic wave device according to the first example embodiment of the present disclosure. An acoustic wave device 81 includes a support substrate 82. The support substrate 82 is provided with a recess opened to an upper surface. A piezoelectric layer 83 is laminated on the support substrate 82. With this, a hollow portion 9 is formed. An IDT electrode 84 is provided on the piezoelectric layer 83 above the hollow portion 9. Reflectors 85 and 86 are provided at both sides in the acoustic wave propagation direction of the IDT electrode 84. In FIG. 12, an outer peripheral edge of the hollow portion 9 is indicated by a broken line. In this case, the IDT electrode 84 includes first and second busbars 84a and 84b, a plurality of electrodes 84c as first electrode fingers, and a plurality of electrodes 84d as second electrode fingers. The plurality of electrodes 84c is connected to the first busbar 84a. The plurality of electrodes 84d is connected to the second busbar 84b. The plurality of electrodes 84c and the plurality of electrodes 84d interdigitate with each other.

In the acoustic wave device 81, an AC electric field is applied to the IDT electrode 84 above the hollow portion 9 to excite a Lamb wave as a plate wave. Since the reflectors 85 and 86 are provided at both the sides, resonance characteristics generated by the Lamb wave can be obtained.

As described above, an acoustic wave device according to an example embodiment of the present disclosure may utilize a plate wave.

### Second Example Embodiment

An acoustic wave device of a second example embodiment will be described below. In the second example embodiment, description of the same contents as those in the first example embodiment will be omitted as appropriate. The contents described in the first example embodiment may be applied to the second example embodiment.

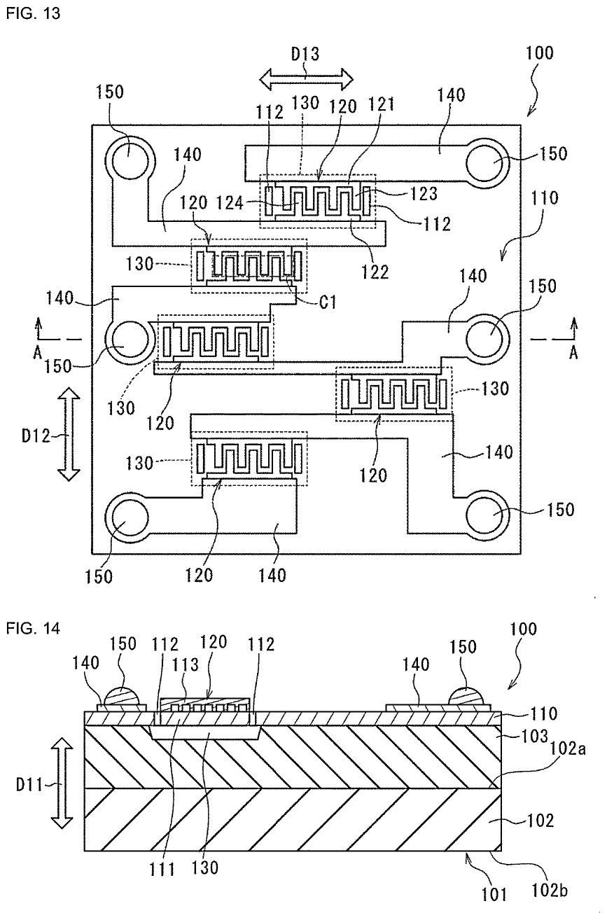

FIG. 13 is a schematic plan view of an acoustic wave device according to the second example embodiment of the present disclosure. FIG. 14 is a schematic cross-sectional view of the acoustic wave device taken along a line A-A in FIG. 13. As illustrated in FIGS. 13 and 14, an acoustic wave device 100 includes a support 101, a piezoelectric layer 110, and a resonator 120. The support 101 is provided with a hollow portion 130, and a wiring electrode 140 is electrically connected to the resonator 120. A bump 150 electrically connected to the wiring electrode 140 is provided on the wiring electrode 140. In the present specification, the acoustic wave device 100 may be referred to as an acoustic wave element 100.

The support 101 includes a support substrate 102 and an intermediate layer 103. For example, the support 101 is including a multilayer body of the support substrate 102 including Si and the intermediate layer 103 laminated on the support substrate 102 and including SiOx. In the present specification, the intermediate layer 103 may be referred to as a bonding layer 103.

The support substrate 102 is a substrate having a thickness in a first direction D11. In the present specification, the “first direction” is a thickness direction of the support substrate 102, and means a lamination direction in which the support 101 and the piezoelectric layer 110 are laminated. The thickness of the support substrate 102 is less than about 250 μm, for example. In other words, the dimension in the first direction D11 of the support substrate 102 is less than about 250 μm, for example.

The support substrate 102 includes a first surface 102a and a second surface 102b opposing each other in the first direction D11. The bonding layer 103 is laminated on the first surface 102a of the support substrate 102. The surface roughness of the second surface 102b of the support substrate 102 is rougher than that of the piezoelectric layer 110. The edge of the second surface 102b of the support substrate 102 is roughened by being cut with a dicing machine when manufacturing the acoustic wave device 100.

The support 101 is provided with the hollow portion 130. In the present specification, the hollow portion 130 may be referred to as a space portion 130.

The hollow portion 130 is provided between the support 101 and the piezoelectric layer 110. In other words, the hollow portion 130 is a space defined by the support 101 and the piezoelectric layer 110. In the present example embodiment, the hollow portion 130 is provided in the intermediate layer 103. Specifically, there is provided a recess that is opened to a surface of the intermediate layer 103 on the opposite side to a surface thereof in contact with the support substrate 102. The hollow portion 130 is defined by the recess being covered with the piezoelectric layer 110.

It is sufficient for the hollow portion 130 to be provided in a portion of the support 101. In a case where the support 101 does not include the intermediate layer 103, the hollow portion 130 may be provided in the support substrate 102.

The piezoelectric layer 110 is provided on the support 101. The piezoelectric layer 110 is laminated in the first direction D11 of the support 101. In the present example embodiment, the piezoelectric layer 110 is provided on the intermediate layer 103. That is, the piezoelectric layer 110 is provided on the support substrate 102 with the bonding layer 103 interposed therebetween. Specifically, the piezoelectric layer 110 is provided on the surface of the intermediate layer 103 on the opposite side to the surface thereof in contact with the support substrate 102. In the present specification, the piezoelectric layer 110 may be referred to as a piezoelectric material layer 110 or a piezoelectric substrate 110.

In the present specification, a portion of the piezoelectric layer 110 located in a region overlapping the hollow portion 130 in plan view in the first direction D11 is referred to as a membrane portion 111. The expression “in plan view in the first direction D11” means viewing from a lamination direction of the support 101 and the piezoelectric layer 110.

The hollow portion 130 is preferably provided in the support 101 at a position overlapping at least a portion of the resonator 120 in plan view in the first direction D11.

The piezoelectric layer 110 includes, for example, LiNbOx or LiTaOx. In other words, the piezoelectric layer 110 includes lithium niobate or lithium tantalate. The piezoelectric layer 110 is thinner than the intermediate layer 103.

The resonator 120 includes a functional electrode provided on the piezoelectric layer 110. In the present specification, the functional electrode may be referred to as an electrode portion. In the present example embodiment, the functional electrode is an IDT electrode. The IDT electrode includes a first busbar 121 and a second busbar 122 facing each other, a plurality of first electrode fingers 123 connected to the first busbar 121, and a plurality of second electrode fingers 124 connected to the second busbar 122. The plurality of first electrode fingers 123 and the plurality of second electrode fingers 124 interdigitate with each other, and the first electrode finger 123 and the second electrode fingers 124 adjacent to each other are paired to define an electrode set.

The plurality of first electrode fingers 123 and the plurality of second electrode fingers 124 extend in a second direction D12 intersecting with the first direction D11, and overlap each other when viewed from a third direction D13 orthogonal to the second direction D12. The second direction D12 is a direction intersecting the lamination direction in which the support 101 and the piezoelectric layer 110 are laminated, in a plane direction of the piezoelectric layer 110. The plane direction of the piezoelectric layer 110 is a direction in which the front surface of the piezoelectric layer 110 extends in plan view in the first direction D11. The third direction D13 is a direction orthogonal to the second direction D12 in plan view in the first direction D11, and is also a direction in which the plurality of first electrode fingers 123 and the plurality of second electrode fingers 124 are aligned. That is, the third direction D13 is a facing direction in which the plurality of first electrode fingers 123 and the plurality of second electrode fingers 124 adjacent to each other face each other.

When viewed from the first direction D11, the plurality of first electrode fingers 123 and the plurality of second electrode fingers 124 are adjacent to and facing each other. When viewed from the third direction D13, the plurality of first electrode fingers 123 and the plurality of second electrode fingers 124 overlap with each other. That is, the plurality of first electrode fingers 123 and the plurality of second electrode fingers 124 are alternately provided in the third direction D13. Specifically, the first electrode finger 123 and the second electrode finger 124 adjacent to each other face each other, and are paired to define an electrode set. In the resonator 120, a plurality of the electrode sets is provided in the third direction D13.

The plurality of first electrode fingers 123 extends in the second direction D12 intersecting with the first direction D11. The base ends of the plurality of first electrode fingers 123 are connected to the first busbar 121. The plurality of second electrode fingers 124 faces any of the plurality of first electrode fingers 123 in the third direction D13 orthogonal to the second direction D12 and extend in the second direction D12. The base ends of the plurality of second electrode fingers 124 are connected to the second busbar 122.

A region in which the plurality of first electrode fingers 123 and the plurality of second electrode fingers 124 overlap each other in the third direction D13 is an excitation region C1. That is, the excitation region C1 is a region where the plurality of first electrode fingers 123 and the plurality of second electrode fingers 124 overlap each other when viewed in a direction in which the adjacent first electrode fingers 123 and second electrode fingers 124 face each other, that is, when viewed in the third direction D13. In the present specification, the excitation region C1 may be referred to as an overlap region C1.

The IDT electrode is provided on the piezoelectric layer 110 at a position overlapping the hollow portion 130 in plan view in the first direction D11. To be specific, the hollow portion 130 is provided at a position overlapping the first busbar 121, the second busbar 122, the plurality of first electrode fingers 123, and the plurality of second electrode fingers 124 in plan view in the first direction D11. In other words, the IDT electrode is provided in the membrane portion 111. It is sufficient for the IDT electrode to be provided in at least a portion of the membrane portion 111 in plan view in the first direction D11.

As illustrated in FIG. 13, the IDT electrode is connected to the wiring electrode 140. Specifically, the wiring electrode 140 is provided to the first busbar 121 and the second busbar 122. The wiring electrode 140 is electrically connected to the first busbar 121 and the second busbar 122.

The wiring electrode 140 is disposed to overlap each of the first busbar 121 and the second busbar 122 in plan view in the first direction D11.

It is sufficient that the wiring electrode 140 is provided for at least one of the first busbar 121 and the second busbar 122.

The bump 150 is provided on the wiring electrode 140. The bump 150 is electrically connected to the wiring electrode 140.

The piezoelectric layer 110 is provided with a plurality of through holes 112 extended to reach the hollow portion 130. The plurality of through holes 112 is provided at both outer side portions of the IDT electrode in the third direction D13 in plan view in the first direction D11. The plurality of through holes 112 communicates with the hollow portion 130. The plurality of through holes 112 has, for example, a rectangular or substantially rectangular shape in plan view in the first direction D11.

As illustrated in FIG. 14, a dielectric film 113 (not illustrated in FIG. 13) is provided on the piezoelectric layer 110 to cover the IDT electrode. In the present specification, the dielectric film 113 may be referred to as a frequency adjustment film 113.

### Method for Manufacturing Acoustic Wave Device

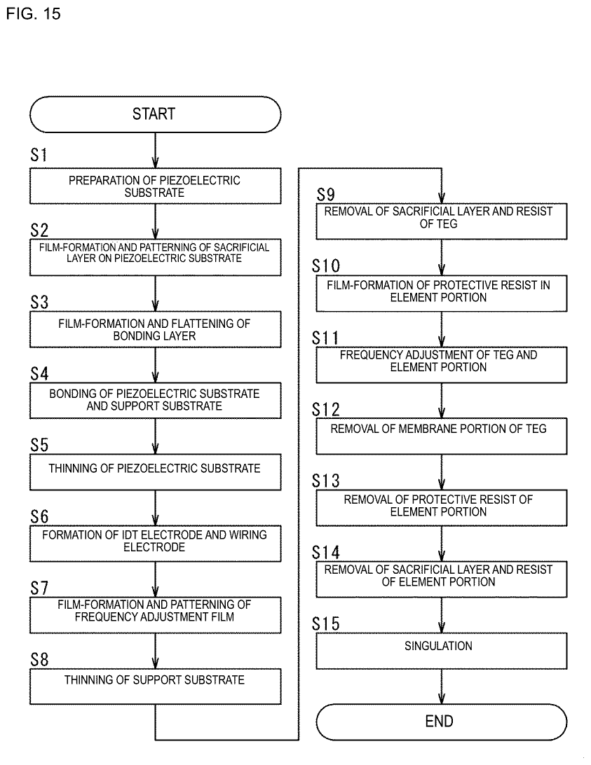

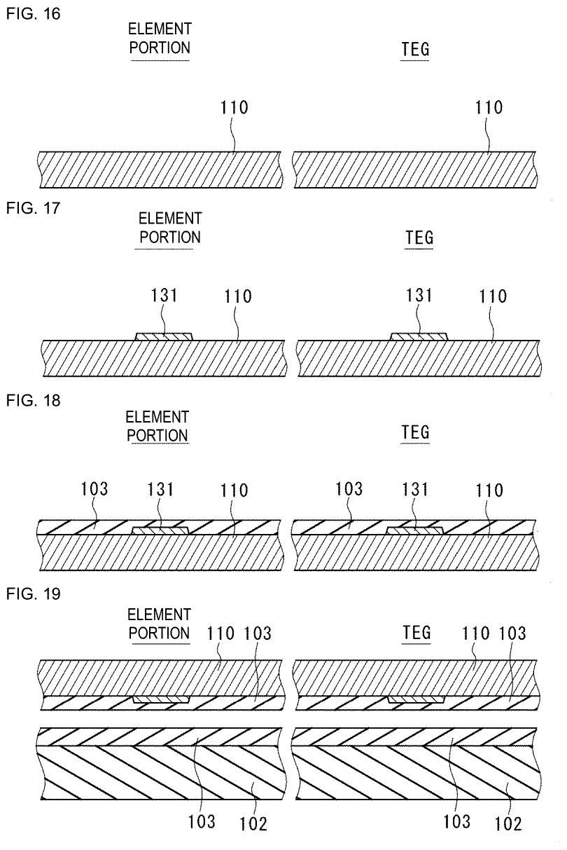

Hereinafter, a non-limiting example of a method for manufacturing the acoustic wave device according to the second example embodiment (the acoustic wave device 100 illustrated in FIGS. 13 and 14) will be described with reference to FIGS. 15 to 24. Note that in FIGS. 16 to 27, an element portion and a test element group (TEG) are illustrated. The element portion is a portion to become the acoustic wave device 100 through a manufacturing process, and the TEG is a portion for adjusting characteristics (frequency characteristics in the present example embodiment) of the element portion. In the following description, the same processing is performed on both the element portion and the TEG in each step of the manufacturing method unless the element portion or the TEG is particularly specified.

Referring to FIG. 15, in step S1, the piezoelectric substrate 110 is prepared as illustrated in FIG. 16.

In step S2, as illustrated in FIG. 17, a sacrificial layer 131 is film-formed on the piezoelectric substrate 110, a portion of the film-formed sacrificial layer 131 is removed, and a pattern of the sacrificial layer 131 is printed (patterning). Film-formation of the sacrificial layer 131 on the piezoelectric substrate 110 may be performed by a known method such as chemical vapor deposition, physical vapor deposition, or a combination thereof. The removal of the sacrificial layer 131 may be performed by a known method such as etching.

In step S3, as illustrated in FIG. 18, the bonding layer 103 is film-formed on the piezoelectric substrate 110 and flattened. The bonding layer 103 is film-formed to cover the sacrificial layer 131. Film-formation of the bonding layer 103 on the piezoelectric substrate 110 may be performed by a known method such as chemical vapor deposition, physical vapor deposition, or a combination thereof. Flattening of the bonding layer 103 may be performed by a known method such as polishing, etching, or a combination thereof.

In step S4, as illustrated in FIG. 19, the piezoelectric substrate 110, on which the bonding layer 103 is formed, and the support substrate 102, on which the bonding layer 103 is formed, are bonded to each other. At this time, the bonding layer 103 on the piezoelectric substrate 110 and the bonding layer 103 on the support substrate 102 are bonded. By carrying out step S1 to step S4, a wafer 300, in which the support substrate 102 and the piezoelectric substrate 110 are laminated, is prepared.

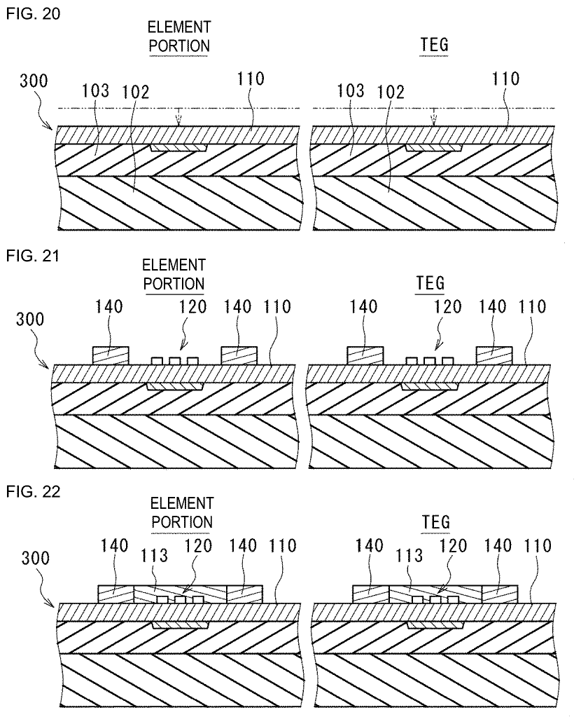

In step S5, as illustrated in FIG. 20, the piezoelectric substrate 110 is thinned. Thinning of the piezoelectric substrate 110 may be performed by a known method such as polishing, etching, or a combination thereof. In FIG. 20, a surface of the piezoelectric substrate 110 before being thinned on the opposite side to a surface thereof in contact with the bonding layer 103 is indicated by a two-dot chain line.

In step S6, as illustrated in FIG. 21, the resonator 120 and the wiring electrode 140 are formed on the piezoelectric substrate 110. In step S6, the IDT electrode is formed on the piezoelectric substrate 110. Formation of the resonator 120 and the wiring electrode 140 on the piezoelectric substrate 110 may be performed by a known method such as lift-off vapor deposition.

In step S7, as illustrated in FIG. 22, the frequency adjustment film 113 is film-formed on the IDT electrode and patterned. That is, a portion of the film-formed frequency adjustment film 113 is removed, and the pattern of the frequency adjustment film 113 is printed on the IDT electrode.

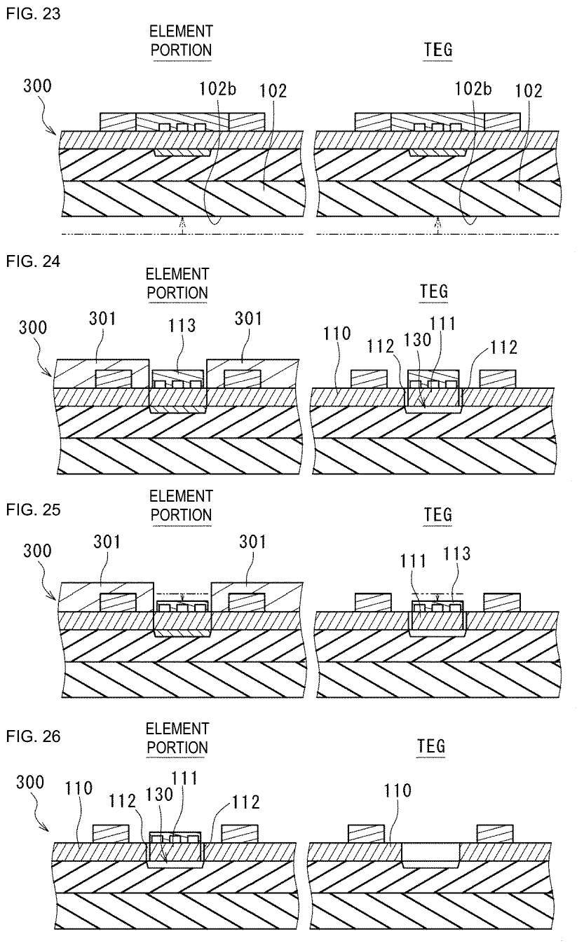

In step S8, as illustrated in FIG. 23, the support substrate 102 is thinned. Thinning of the support substrate 102 may be performed by a known method such as polishing. For example, the second surface 102b of the support substrate 102 is polished to thin the support substrate 102. In FIG. 23, the second surface 102b of the support substrate 102 before being thinned is indicated by a two-dot chain line.

In step S9, as illustrated in FIG. 24, in the TEG, the through hole 112 for removing the sacrificial layer 131 (depicted in FIG. 23) is formed in the piezoelectric substrate 110 by resist patterning and etching. Thereafter, the sacrificial layer 131 is removed by etching through the through hole 112, and the hollow portion 130 and the membrane portion 111 are formed in the TEG.

In step S10, as illustrated in FIG. 24, in the element portion, a protective resist 301 is film-formed on a portion other than the frequency adjustment film 113 in such a manner as to expose the frequency adjustment film 113.

In step S11, as illustrated in FIG. 25, in the element portion and the TEG, the frequency adjustment film 113 is trimmed to adjust the thickness of the frequency adjustment film 113, whereby the frequency characteristics of the IDT electrode are adjusted. The adjustment of the frequency characteristics is performed by trimming the frequency adjustment film 113 until the desired frequency characteristics of the IDT electrode are obtained in the TEG. The trimming of the frequency adjustment film 113 may be performed by a known method. In FIG. 25, a surface of the frequency adjustment film 113 before being trimmed on the opposite side to a surface thereof in contact with the piezoelectric substrate 110 is indicated by a two-dot chain line.

Step S10 and step S11 may be repeated until the frequency characteristics of all the resonators 120 included in the element portion (for example, five resonators 120 in the case of manufacturing the acoustic wave element 100 illustrated in FIG. 13) are adjusted. In this case, the membrane portion 111 of the TEG used for the frequency adjustment of one resonator 120 is removed by high-pressure jet cleaning or the like after the frequency adjustment of the one resonator 120 is completed. Therefore, the number of TEGs is preferably larger than at least the number of resonators 120 included in the element portion.

In step S12, as illustrated in FIG. 26, the protective resist 301 (depicted in FIG. 25) in the element portion is removed. Thereafter, in the element portion, the through hole 112 for removing the sacrificial layer 131 (depicted in FIG. 25) is formed in the piezoelectric substrate 110 by resist patterning and etching. Thereafter, the sacrificial layer 131 is removed by etching through the through hole 112, and the hollow portion 130 and the membrane portion 111 are formed in the element portion.

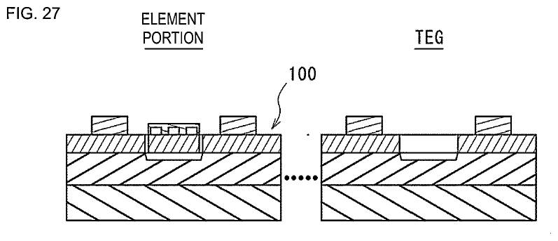

Finally, in step S13, as illustrated in FIG. 27, the wafer 300 is cut with a dicing machine to singulate into a plurality of the acoustic wave devices 100 from the wafer 300. In the present example embodiment, laser dicing such as stealth dicing can be used as a dicing technique.

Although not illustrated, the bump 150 (FIG. 13) may be formed in the manufactured acoustic wave device 100.

An example of a method for manufacturing the acoustic wave device according to the present example embodiment includes preparing the wafer 300 with the support substrate 102 and the piezoelectric material layer 110 laminated therein, thinning the support substrate 102 of the wafer 300, and after the thinning the support substrate 102, cutting the wafer 300 with a dicing machine to singulate into the acoustic wave devices 100.

According to the above-described manufacturing method, since the support substrate 102 is thinned before the wafer 300 is cut with a dicing machine, the dimension of height of the acoustic wave device 100, that is, the size in the first direction D11 can be reduced as compared to a case where the support substrate 102 is not thinned. As a result, the acoustic wave device 100 may be reduced in size.

In the present example embodiment, when the wafer 300 is prepared, the sacrificial layer 131 is formed between the piezoelectric material layer 110 and the support substrate 102, the functional electrode is formed on the piezoelectric material layer 110 before the support substrate 102 is thinned, and the sacrificial layer 131 is removed after the support substrate 102 is thinned. According to the above-described manufacturing method, the support substrate 102 is thinned in a state where the sacrificial layer 131 is present in the wafer 300, thereby making it possible to reduce or prevent occurrence of a situation in which the wafer 300 is damaged due to the thinning of the support substrate 102.

In the present example embodiment, before the support substrate 102 is thinned, the functional electrode is formed on the piezoelectric material layer 110. With such manufacturing method, it is possible to reduce or prevent occurrence of a situation in which the support substrate 102 warps when the functional electrode is formed on the piezoelectric material layer 110. As a result, the functional electrode may be easily formed on the piezoelectric substrate 110.

In the present example embodiment, the support substrate 102 is thinned after all of the functional electrodes and wiring electrodes are formed on the piezoelectric material layer 110 by lift-off vapor deposition and before the sacrificial layers 131 of the TEG and the element portion are removed.

In the present example embodiment, the example in which a through hole 112 is respectively provided at each of the outer side portions of the resonators 120 has been described, but the present invention is not limited thereto. For example, one or more through holes 112 may be provided at least at any one of the outer side portions of the resonator 120.

In the present example embodiment, the example in which the hollow portion 130 is provided at a position overlapping the first busbar 121 and the second busbar 122 in plan view in the first direction D11 has been described, but the present invention is not limited thereto. For example, the hollow portion 130 may be provided at a position overlapping neither the first busbar 121 nor the second busbar 122 in plan view in the first direction D11.

The through hole 112 may also be used as an etching hole for introducing an etchant, for example.

In the present example embodiment, the example in which the IDT electrode is provided on the piezoelectric layer 110 has been described, but the present invention is not limited thereto. It is sufficient for the IDT electrode to be provided to the piezoelectric layer 110 in the first direction D11. For example, the IDT electrode may be provided on a side of the piezoelectric layer 110 where the hollow portion 130 is provided.

Hereinafter, a modification of the second example embodiment will be described.

### Modification 1

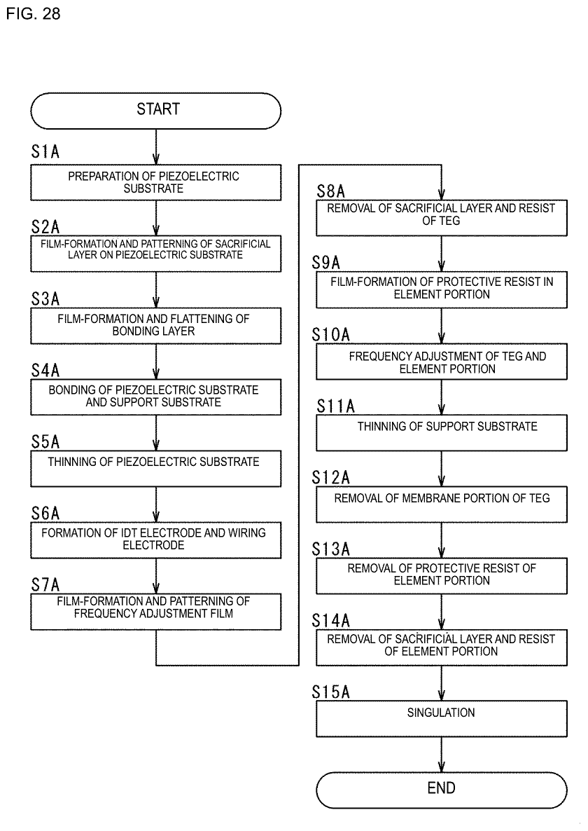

FIG. 28 is a flowchart illustrating a method for manufacturing an acoustic wave device of Modification 1. The method for manufacturing the acoustic wave device of Modification 1 differs from the method for manufacturing the acoustic wave device of the second example embodiment in that the support substrate 102 is thinned after the frequency adjustment film 113 is trimmed to adjust the frequency characteristics of the IDT electrode. That is, the method for manufacturing the acoustic wave device of Modification 1 differs from the method for manufacturing the acoustic wave device of the second example embodiment in a timing at which the support substrate 102 is thinned. In Modification 1, detailed description of the same contents as those in the second example embodiment will be omitted as appropriate.

Referring to FIG. 28, steps S1A to S7A in the method for manufacturing the acoustic wave device of Modification 1 are the same as steps S1 to S7 (illustrated in FIG. 15), respectively, in the method for manufacturing the acoustic wave device of the second example embodiment, and therefore detailed description thereof will be omitted.

Steps S8A to S10A are similar to steps S9 to S11 (illustrated in FIG. 15), respectively, in the method for manufacturing the acoustic wave device of the second example embodiment, and therefore detailed description thereof will be omitted. Steps S8A to S10A are different from steps S9 to S11 in the method for manufacturing the acoustic wave device of the second example embodiment in that the support substrate 102 is not thinned.

Step S11A is similar to step S8 (illustrated in FIG. 15) in the method for manufacturing the acoustic wave device of the second example embodiment, and therefore detailed description thereof will be omitted. Step S11A differs from step S8 in the method for manufacturing the acoustic wave device of the second example embodiment in that the support substrate 102 is thinned in a state where the frequency adjustment film 113 is trimmed and the frequency characteristics of the IDT electrode are adjusted.

Steps S12A to S15A are the same as steps S12 to S15 (illustrated in FIG. 15), respectively, in the method for manufacturing the acoustic wave device of the second example embodiment, and therefore detailed description thereof will be omitted.

According to such manufacturing method as well, the acoustic wave device 100 may be reduced in size.

The method for manufacturing the acoustic wave device of Modification 1 includes forming the frequency adjustment film 113 on the piezoelectric material layer 110 and adjusting the thickness of the frequency adjustment film 113 before the support substrate 102 is thinned. According to such manufacturing method, since the support substrate 102 is thinned after the thickness of the frequency adjustment film 113 is adjusted, it is possible to reduce or prevent occurrence of a situation in which the wafer 300 is damaged when the thickness of the frequency adjustment film 113 is adjusted.

### Modification 2

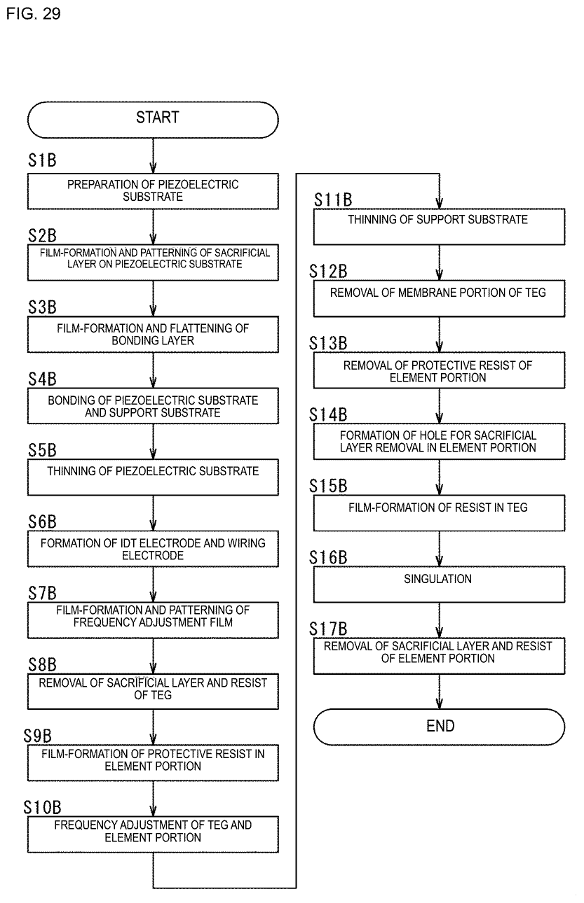

FIG. 29 is a flowchart illustrating a method for manufacturing an acoustic wave device of Modification 2 of an example embodiment of the present invention. The manufacturing method of Modification 2 is different from the manufacturing method for the acoustic wave device of Modification 1 in that a resist is formed in the element portion and the TEG before the wafer 300 is cut with a dicing machine to singulate into the plurality of acoustic wave devices 100 from the wafer 300. In Modification 2, detailed description of the same contents as those in Modification 1 will be omitted as appropriate.

Referring to FIG. 29, steps S1B to S13B in the method for manufacturing the acoustic wave device of Modification 2 are the same as steps S1A to S13A (illustrated in FIG. 28), respectively, in the method for manufacturing the acoustic wave device of Modification 1, and therefore detailed description thereof will be omitted.

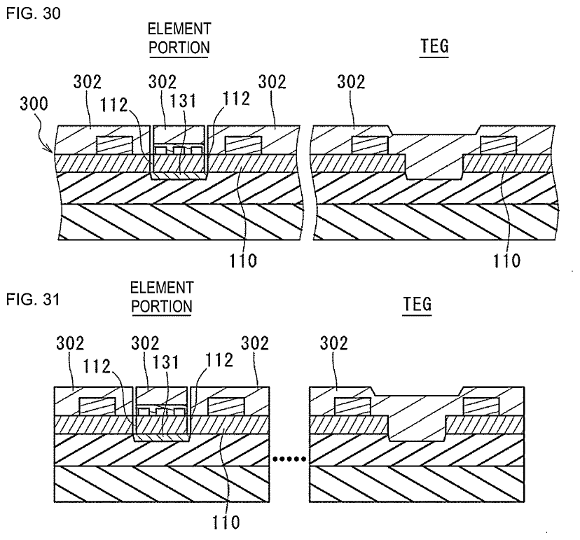

In step S14B, as illustrated in FIG. 30, in the element portion, the through hole 112 for removing the sacrificial layer 131 is formed in the piezoelectric substrate 110 by resist patterning and etching, and a protective resist 302 is film-formed on the piezoelectric substrate 110.

In step S15B, as illustrated in FIG. 30, the protective resist 302 is formed on the entire surface of the piezoelectric substrate 110 in the TEG.

In step S16B, as illustrated in FIG. 31, the wafer 300 is cut with a dicing machine to separate individual acoustic wave devices from the wafer 300. In the present example embodiment, for example, blade dicing can be used as a dicing technique.

In step S17B, although not illustrated, in the element portion, the sacrificial layer 131 is removed by etching through the through hole 112, and the hollow portion 130 and the membrane portion 111 are formed in the element portion. Further, in the element portion, the protective resist 302 is removed and the acoustic wave device 100 is manufactured.

According to such manufacturing method as well, the acoustic wave device may be reduced in size.

The method for manufacturing the acoustic wave device of Modification 2 includes forming the frequency adjustment film 113 on the piezoelectric material layer 110 and adjusting the thickness of the frequency adjustment film 113 before the support substrate 102 is thinned. According to such manufacturing method, since the support substrate 102 is thinned after the thickness of the frequency adjustment film 113 is adjusted, it is possible to reduce or prevent occurrence of a situation in which the wafer 300 is damaged when the thickness of the frequency adjustment film 113 is adjusted.

The method for manufacturing the acoustic wave device of Modification 2 includes cutting the wafer 300 with a dicing machine after the protective resist 302 is film-formed in the element portion and the TEG. According to such manufacturing method, even in a case where blade dicing is used as a dicing technique, since the element portion is protected by the protective resist 302, a situation in which the element portion is damaged by cooling water used in the blade dicing may be reduced or prevented.

### Other Example Embodiments

As described thus far, the above example embodiments have been described as examples of the techniques disclosed in the present application. However, the techniques in the present disclosure are not limited thereto, and are also applicable to example embodiments in which changes, replacements, additions, omissions, and the like can be made as appropriate.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for manufacturing an acoustic wave element including a support substrate, a piezoelectric material layer on the support substrate, and a functional electrode on the piezoelectric material layer, the method comprising:
preparing a wafer in which the support substrate and the piezoelectric material layer are laminated;
thinning the support substrate of the wafer; and
after the thinning the support substrate, cutting the wafer with a dicing machine to singulate the acoustic wave element.

2. The method for manufacturing the acoustic wave element according to claim 1, further comprising:
forming a sacrificial layer between the piezoelectric material layer and the support substrate at a time of the preparing the wafer;
forming the functional electrode on the piezoelectric material layer before the thinning the support substrate; and
removing the sacrificial layer after the thinning the support substrate.

3. The method for manufacturing the acoustic wave element according to claim 1, further comprising:
forming a frequency adjustment film on the piezoelectric material layer and adjusting a thickness of the frequency adjustment film before the thinning the support substrate.

4. The method for manufacturing the acoustic wave element according to claim 1, wherein a surface roughness of a surface of the support substrate is rougher than a surface roughness of the piezoelectric material layer.

5. The method for manufacturing the acoustic wave element according to claim 1, wherein the support substrate has a thickness of about 250 μm or less.

6. The method for manufacturing the acoustic wave element according to claim 1, wherein the functional electrode is an IDT electrode.

7. The method for manufacturing the acoustic wave element according to claim 1, wherein the acoustic wave element is configured to generate a bulk wave in a thickness-shear mode.

8. The method for manufacturing the acoustic wave element according to claim 1, wherein the piezoelectric material layer is made of lithium niobate or lithium tantalate.

9. The method for manufacturing the acoustic wave element according to claim 6, wherein
the IDT electrode includes a first electrode finger and a second electrode finger facing each other in a direction intersecting a lamination direction of the support substrate and the piezoelectric material layer;
the first electrode finger and the second electrode finger are electrodes adjacent to each other; and
in a case that a thickness of the piezoelectric material layer is d and a center-to-center distance between the first electrode finger and the second electrode finger is p, d/p is about 0.5 or less.

10. The method for manufacturing the acoustic wave element according to claim 9, wherein the d/p is about 0.24 or less.

11. The method for manufacturing the acoustic wave element according to claim 9, wherein a metalization ratio MR, which is a ratio of an area of the first electrode finger and the second electrode finger within an excitation region to an area of the excitation region, satisfies a relation of MR≤ about 1.75 (d/p)+0.075, the excitation region being a region where the first electrode finger and the second electrode finger overlap each other in a direction intersecting the lamination direction.

12. The method for manufacturing the acoustic wave element according to claim 8, wherein Euler angles (φ, θ, ψ) of the lithium niobate or the lithium tantalate are in a range of Formula (1), (2), or (3):
(0°±10°,0° to 20°, optional ψ) Formula(1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Formula (2); and
(0°±10°,[180°−30°(1−(ψ−90)²/8100)^{1/2}] to 180°, optional ψ) Formula(3).

13. An acoustic wave element comprising:
a support substrate including a first surface and a second surface opposing each other;
a piezoelectric material layer on the first surface; and
a functional electrode on the piezoelectric material layer;
wherein
a surface roughness of the second surface is rougher than a surface roughness of the piezoelectric material layer; and
the support substrate has a thickness of about 250 μm or less.

14. The acoustic wave element according to claim 13, wherein the functional electrode is an IDT electrode.

15. The acoustic wave element according to claim 13, wherein the acoustic wave element is configured to generate a bulk wave in a thickness-shear mode.

16. The acoustic wave element according to claim 15, wherein
the piezoelectric material layer is made of lithium niobate or lithium tantalate;
the IDT electrode includes a first electrode finger and a second electrode finger facing each other in a direction intersecting a lamination direction of the support substrate and the piezoelectric material layer;
the first electrode finger and the second electrode finger are electrodes adjacent to each other; and
in a case that a thickness of the piezoelectric material layer is d and a center-to-center distance between the first electrode finger and the second electrode finger is p, d/p is about 0.5 or less.

17. The acoustic wave element according to claim 16, wherein the d/p is about 0.24 or less.

18. The acoustic wave element according to claim 16, wherein a metalization ratio MR, which is a ratio of an area of the first electrode finger and the second electrode finger within an excitation region to an area of the excitation region, satisfies a relation of MR≤ about 1.75 (d/p)+0.075, the excitation region being a region where the first electrode finger and the second electrode finger overlap each other in a direction intersecting the lamination direction.

19. The acoustic wave element according to claim 16, wherein Euler angles (φ, θ, ψ) of the lithium niobate or the lithium tantalate are in a range of Formula (1), (2), or (3):
(0°±10°,0° to 20°, optional ψ) Formula(1);
(0°±10°,20° to 80°, 0° to 60°(1−(θ−50)²/900)^{1/2}) or (0°±10°,20° to 80°,[180°−60°(1−(θ−50)²/900)^{1/2}] to 180°) Formula(2); and
(0°±10°,[180°−30°(1−(ψ−90)²/8100)^{1/2}] to 180°, optional ψ)Formula(3).
